(19) United States
(12) Patent Application Publication
(10) Pub. No.: US 2023/0163256 A1
(43) Pub. Date: May 25, 2023

(54) LIGHT SOURCE DEVICE AND PROJECTOR

(71) Applicant: SEIKO EPSON CORPORATION, Tokyo (JP)

(72) Inventors: Junichi SUZUKI, Matsumoto-shi (JP); Hidefumi SAKATA, Azumino-shi (JP); Yuichiro IWAMA, Azumino-shi (JP); Shingo KOMIYAMA, Chino-shi (JP)

(21) Appl. No.: 17/989,845

(22) Filed: Nov. 18, 2022

(30) Foreign Application Priority Data
Nov. 19, 2021 (JP) 2021-188539

(51) Int. Cl. H01L 33/50; H01L 33/52

(52) U.S. Cl. CPC H01L 33/504; H01L 33/52

(57) ABSTRACT

A light source device according to the present disclosure includes a light emitting element having a light emitting surface configured to emit first light having a first wavelength band, a wavelength conversion member which includes a phosphor, and which is configured to convert the first light emitted from the light emitting element into second light having a second wavelength band different from the first wavelength band, and a reflecting member having a reflecting surface configured to reflect the second light generated by the wavelength conversion member. The wavelength conversion member has a first face which crosses a longitudinal direction of the wavelength conversion member, and which emits the second light, a second face which crosses the longitudinal direction of the wavelength conversion member, and which is located at an opposite side to the first face, and a third face crossing the first face and the second face. The light emitting surface is disposed so as to be opposed to at least a part of the third face. The reflecting surface is disposed so as to be opposed to the second face. At least one of the second face and the reflecting surface is a rough surface.

The present application is based on, and claims priority from JP Application Serial Number 2021-188539, filed Nov. 19, 2021, the disclosure of which is hereby incorporated by reference herein in its entirety.

### BACKGROUND

### 1. Technical Field

The present disclosure relates to a light source device and a projector.

### 2. Related Art

As a light source device used for a projector, there is proposed a light source device using fluorescence emitted from a phosphor when irradiating the phosphor with excitation light emitted from a light emitting element.

In International Patent Publication No. WO 2020/254455, there is disclosed a light source device provided with an excitation light source for emitting excitation light, a phosphor shaped like a rod for converting the excitation light into fluorescence, and a mirror for reflecting the fluorescence generated inside the phosphor. The fluorescence is emitted from one end surface of the phosphor. The mirror is disposed on an end surface at an opposite side to the end surface from which the fluorescence is emitted.

However, in the light source device in WO 2020/254455 a part of the fluorescence generated inside the phosphor is not taken out from the end surface, but is confined inside the phosphor in some cases. Therefore, there is a possibility that the fluorescence having desired intensity cannot be obtained.

### SUMMARY

In view of the problems described above, a light source device according to an aspect of the present disclosure includes a light emitting element having a light emitting surface configured to emit first light having a first wavelength band, a wavelength conversion member which includes a phosphor, and which is configured to convert the first light emitted from the light emitting element into second light having a second wavelength band different from the first wavelength band, and a reflecting member having a reflecting surface configured to reflect the second light generated by the wavelength conversion member. The wavelength conversion member has a first face which crosses a longitudinal direction of the wavelength conversion member, and which emits the second light, a second face which crosses the longitudinal direction of the wavelength conversion member, and which is located at an opposite side to the first face, and a third face crossing the first face and the second face. The light emitting surface is disposed so as to be opposed to at least a part of the third face. The reflecting surface is disposed so as to be opposed to the second face. At least one of the second face and the reflecting surface is a rough surface.

A projector according to an aspect of the present disclosure includes the light source device according to the aspect of the present disclosure, a light modulation device configured to modulate light including the second light from the light source device in accordance with image information, and a projection optical device configured to project the light modulated by the light modulation device.

### BRIEF DESCRIPTION OF THE DRAWINGS

FIG. 1 is a schematic configuration diagram of a projector according to a first embodiment.

FIG. 2 is a schematic configuration diagram of a first illumination device according to the first embodiment.

FIG. 3 is a schematic configuration diagram of a first illumination device according to a comparative example.

FIG. 4 is a schematic configuration diagram of a first illumination device according to a second embodiment.

FIG. 5 is a schematic configuration diagram of a first illumination device according to a third embodiment.

FIG. 6 is a schematic configuration diagram of a first illumination device according to a fourth embodiment.

FIG. 7 is a schematic configuration diagram of a first illumination device according to a fifth embodiment.

### DESCRIPTION OF EXEMPLARY EMBODIMENTS

### First Embodiment

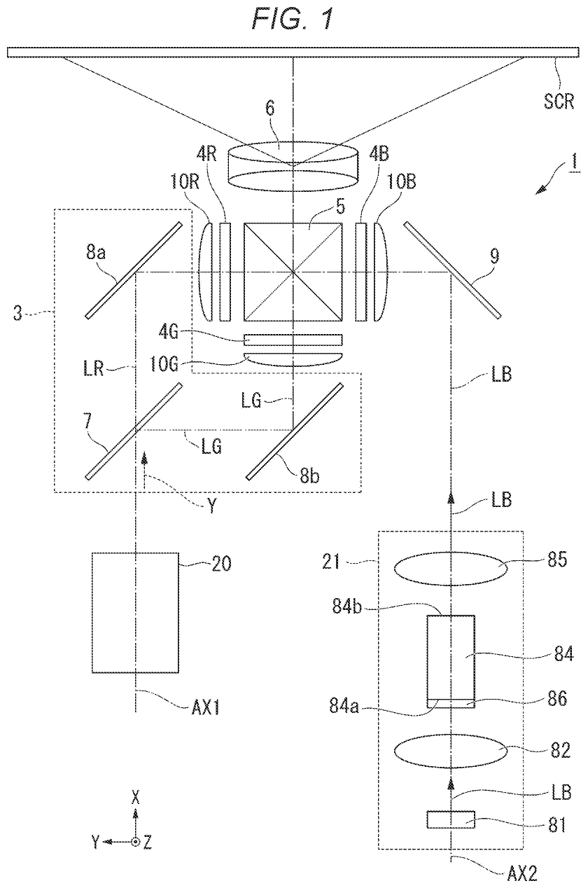

A first embodiment of the present disclosure will hereinafter be described using FIG. 1 through FIG. 3.

A projector according to the present embodiment is an example of a projector using liquid crystal panels as light modulation devices.

In the drawings described below, constituents are shown with respective dimensional scale ratios different from each other in some cases in order to make the constituents eye-friendly.

FIG. 1 is a diagram showing a schematic configuration of the projector 1 according to the present embodiment.

As shown in FIG. 1, the projector 1 according to the present embodiment is a projection-type image display device for displaying a color image on a screen (a projection target surface) SCR. The projector 1 is provided with three light modulation devices corresponding to respective colored light, namely red light LR, green light LG, and blue light LB.

The projector 1 is provided with a first illumination device 20, a second illumination device 21, a color separation optical system 3, a light modulation device 4R, a light modulation device 4G, a light modulation device 4B, a light combining element 5, and a projection optical device 6.

The first illumination device 20 emits fluorescence Y having a yellow color toward the color separation optical system 3. The second illumination device 21 emits the blue light LB toward the light modulation device 4B. The detailed configurations of the first illumination device 20 and the second illumination device 21 will be described later.

Hereinafter, in the drawings, the explanation will be presented using an XYZ coordinate system as needed. A Z axis is an axis extending along a vertical direction of the projector 1. An X axis is an axis parallel to an optical axis AX1 of the first illumination device 20 and an optical axis AX2 of the second illumination device 21. A Y axis is an axis perpendicular to the X axis and the Z axis. The optical axis AX1 of the first illumination device 20 is a central axis of the fluorescence Y emitted from the first illumination device 20. The optical axis AX2 of the second illumination device 21 is a central axis of the blue light LB emitted from the second illumination device 21.

The color separation optical system 3 separates the fluorescence Y having the yellow color emitted from the first illumination device 20 into the red light LR and the green light LG. The color separation optical system 3 is provided with a dichroic mirror 7, a first reflecting mirror 8a, and a second reflecting mirror 8b.

The dichroic mirror 7 separates the fluorescence Y into the red light LR and the green light LG. The dichroic mirror 7 transmits the red light LR, and at the same time, reflects the green light LG. The second reflecting mirror 8b is disposed in a light path of the green light LG. The second reflecting mirror 8b reflects the green light LG, which has been reflected by the dichroic mirror 7, toward the light modulation device 4G. The first reflecting mirror 8a is disposed in a light path of the red light LR. The first reflecting mirror 8a reflects the red light LR, which has been transmitted through the dichroic mirror 7, toward the light modulation device 4R.

Meanwhile, the blue light LB emitted from the second illumination device 21 is reflected by a reflecting mirror 9 toward the light modulation device 4B.

A configuration of the second illumination device 21 will hereinafter be described.

The second illumination device 21 is provided with a light source 81, a condenser lens 82, a diffuser plate 86, a rod lens 84, and a relay lens 85. The light source 81 is formed of at least one semiconductor laser. The light source 81 emits the blue light LB consisting of a laser beam. It should be noted that the light source 81 is not limited to the semiconductor laser, but can also be formed of an LED for emitting blue light.

The condenser lens 82 is formed of a convex lens. The condenser lens 82 makes the blue light LB emitted from the light source 81 enter the diffuser plate 86 in a state in which the blue light LB emitted from the light source 81 is substantially converged. The diffuser plate 86 diffuses the blue light LB emitted from the condenser lens 82 at a predetermined diffusion angle to generate a substantially homogenous light distribution substantially the same as that of the fluorescence Y emitted from the first illumination device 20. As the diffuser plate 86, there is used, for example, obscured glass made of optical glass.

The blue light LB diffused by the diffuser plate 86 enters the rod lens 84. The rod lens 84 has a prismatic shape extending along a direction of the optical axis AX2 of the second illumination device 21. The rod lens 84 has an end plane of incidence of light 84a disposed at one end, and a light exit end surface 84b disposed at the other end. The diffuser plate 86 is fixed to the end plane of incidence of light 84a of the rod lens 84 via an optical adhesive (not shown). It is desirable to make the refractive index of the diffuser plate 86 and the refractive index of the rod lens 84 coincide with each other as precise as possible.

The blue light LB is emitted from the light exit end surface 84b in the state in which homogeneity of an illuminance distribution is enhanced by propagating through the rod lens 84 while being totally reflected. The blue light LB emitted from the rod lens 84 enters the relay lens 85. The relay lens 85 makes the blue light LB enhanced in homogeneity of the illuminance distribution by the rod lens 84 enter the reflecting mirror 9.

The shape of the light exit end surface 84b of the rod lens 84 is a rectangular shape substantially similar to a shape of an image formation area of the light modulation device 4B. Thus, the blue light LB emitted from the rod lens 84 efficiently enters the image formation area of the light modulation device 4B.

The light modulation device 4R modulates the red light LR in accordance with image information to form image light corresponding to the red light LR. The light modulation device 4G modulates the green light LG in accordance with the image information to form image light corresponding to the green light LG. The light modulation device 4B modulates the blue light LB in accordance with the image information to form image light corresponding to the blue light LB.

As each of the light modulation devices 4R, 4G, and 4B, there is used, for example, a transmissive liquid crystal panel. Further, on the incident side and the exit side of each of the liquid crystal panels, there are respectively disposed polarization plates (not shown). The polarization plate transmits linearly-polarized light of a specific direction.

At the incident side of the light modulation device 4R, there is disposed a field lens 10R. At the incident side of the light modulation device 4G, there is disposed a field lens 10G. At the incident side of the light modulation device 4B, there is disposed a field lens 10B. The field lens 10R collimates a principal ray of the red light LR entering the light modulation device 4R. The field lens 10G collimates a principal ray of the green light LG entering the light modulation device 4G. The field lens 10B collimates a principal ray of the blue light LB entering the light modulation device 4B.

The light combining element 5 combines the image light corresponding respectively to the red light LR, the green light LG, and the blue light LB with each other in response to incidence of the image light respectively emitted from the light modulation device 4R, the light modulation device 4G, and the light modulation device 4B, and then emits the image light thus combined toward the projection optical device 6. As the light combining element 5, there is used, for example, a cross dichroic prism.

The projection optical device 6 is constituted by a plurality of projection lenses. The projection optical device 6 projects the image light having been combined by the light combining element 5 toward the screen SCR in an enlarged manner. Thus, an image is displayed on the screen SCR.

A configuration of the first illumination device 20 will hereinafter be described.

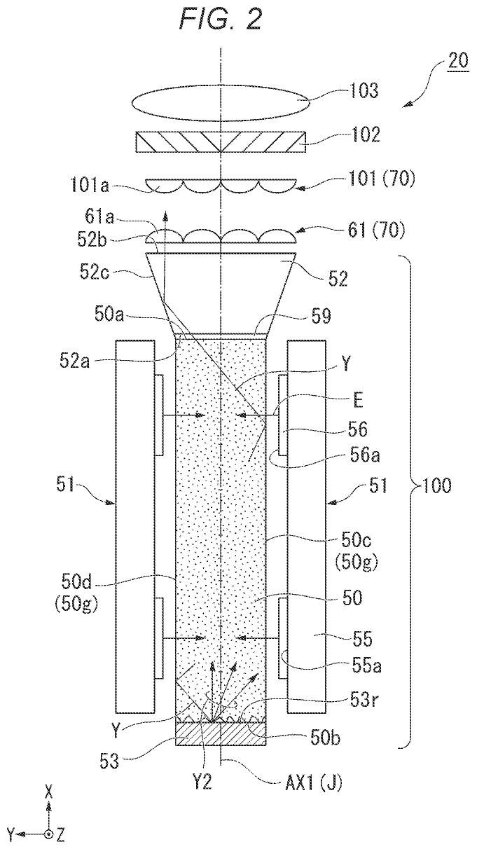

FIG. 2 is a schematic configuration diagram of the first illumination device 20.

As shown in FIG. 2, the first illumination device 20 is provided with a light source device 100, an integrator optical system 70, a polarization conversion element 102, and a superimposing optical system 103.

The light source device 100 is provided with a wavelength conversion member 50, light sources 51, a reflecting member 53, an angle conversion member 52, and a bonding member 59. The light sources 51 are each provided with a substrate 55 and light emitting elements 56.

The wavelength conversion member 50 has a quadrangular prismatic shape extending in the X-axis direction, and has six faces. A side extending in the X-axis direction of the wavelength conversion member 50 is longer than a side extending in the Y-axis direction and a side extending in the Z-axis direction. Therefore, the X-axis direction corresponds to a longitudinal direction of the wavelength conversion member 50. The length of the side extending in the Y-axis direction and the length of the side extending in the Z-axis direction are equal to each other. In other words, a cross-sectional shape of the wavelength conversion member 50 cut by a plane perpendicular to the X-axis direction is a square. It should be noted that the cross-sectional shape of the wavelength conversion member 50 cut by the plane perpendicular to the X-axis direction can be a rectangle.

The wavelength conversion member 50 has a first face 50a which crosses the longitudinal direction (the X-axis direction) of the wavelength conversion member 50, and emits fluorescence Y described later, a second face 50b which crosses the longitudinal direction (the X-axis direction) of the wavelength conversion member 50, and is located at an opposite side to the first face 50a, a first side surface 50c and a second side surface 50d which cross the first face 50a and the second face 50b, and are located at respective sides opposite to each other, and a third side surface and a fourth side surface (not shown) which cross the first side surface 50c and the second side surface 50d, and are located at respective sides opposite to each other. In the following description, four faces, namely the first side surface 50c, the second side surface 50d, the third side surface, and the fourth side surface, are collectively referred to as side surfaces 50g. The side surfaces 50g in the present embodiment correspond to a third surface in the appended claims.

It should be noted that the wavelength conversion member 50 is not necessarily required to have the quadrangular prismatic shape, but can also have other shapes such as a triangular prismatic shape or a cylindrical shape. When the shape of the wavelength conversion member 50 is a triangular prismatic shape, three faces crossing the first face and the second face are collectively referred to as the side surfaces 50g. When the shape of the wavelength conversion member 50 is a cylindrical shape, a single continuous curved surface crossing the first face and the second face is referred to as the side surface 50g.

The wavelength conversion member 50 includes at least a phosphor, and converts excitation light E having a first wavelength band into the fluorescence Y having a second wavelength band different from the first wavelength band. In the present embodiment, the excitation light E enters the wavelength conversion member 50 from each of the first side surface 50c and the second side surface 50d. The fluorescence Y is guided inside the wavelength conversion member 50, and is then emitted from the first face 50a. The excitation light E in the present embodiment corresponds to first light in the appended claims. The fluorescence Y in the present embodiment corresponds to second light in the appended claims.

The wavelength conversion member 50 includes a ceramic phosphor made of a polycrystalline phosphor for performing the wavelength conversion on the excitation light E into the fluorescence Y. The second wavelength band which the fluorescence Y has is a yellow wavelength band of, for example, 490 through 750 nm. Therefore, the fluorescence Y is yellow fluorescence including a red light component and a green light component.

It is also possible for the wavelength conversion member 50 to include a single-crystal phosphor instead of the polycrystalline phosphor. Alternatively, the wavelength conversion member 50 can also be formed of fluorescent glass. Alternatively, the wavelength conversion member 50 can also be formed of a material obtained by dispersing a number of phosphor particles in a binder made of glass or resin. The wavelength conversion member 50 made of such a material converts the excitation light E into the fluorescence Y having the second wavelength band.

Specifically, the material of the wavelength conversion member 50 includes, for example, an yttrium aluminum garnet (YAG) phosphor. Citing YAG:Ce including cerium (Ce) as an activator agent as an example, as the material of the wavelength conversion member 50, there is used a material obtained by mixing raw powder including constituent elements such as Y₂O₃, Al₀ and CeO₃ to cause the solid-phase reaction, Y—Al—O amorphous particles obtained by a wet process such as a coprecipitation process or a sol-gel process, and YAG particles obtained by a gas-phase process such as a spray drying process, a flame heat decomposition process or a thermal plasma process.

The light sources 51 are each provided with the light emitting elements 56 each having a light emitting surface 56a for emitting the excitation light E in the first wavelength band. The light sources 51 are disposed so as to be respectively opposed to the first side surface 50c and the second side surface 50d of the wavelength conversion member 50. The light emitting elements 56 are each formed of, for example, a light emitting diode (LED). As described above, the light sources 51 are each disposed so as to be opposed to a part of the side surfaces 50g along the longitudinal direction of the wavelength conversion member 50. It should be noted that the number and the arrangement of the light sources 51 are not particularly limited.

The light emitting surfaces 56a of the light emitting elements 56 are arranged so as to respectively be opposed to the first side surface 50c and the second side surface 50d of the wavelength conversion member 50, and emit the excitation light E toward the first side surface 50c and the second side surface 50d, respectively. The first wavelength band is, for example, a wavelength band from a blue color to a violet color of 400 nm through 480 nm, and has a peak wavelength of, for example, 445 nm.

The substrate 55 supports the light emitting elements 56. The plurality of light emitting elements 56 is disposed on one surface 55a of the substrate 55. The light sources 51 are each constituted by the light emitting elements 56 and the substrate 55 in the case of the present embodiment, but can also be provided with other optical members such as a light guide plate, a diffuser plate, or a lens. Further, the number of the light emitting elements 56 provided to the substrate 55 is not particularly limited.

The reflecting member 53 is disposed so as to be opposed to the second face 50b of the wavelength conversion member 50. The reflecting member 53 reflects the fluorescence Y which has been guided inside the wavelength conversion member 50, and has reached the second face 50b. The reflecting member 53 is a member separated from the wavelength conversion member 50, and is formed of a plate-like member made of a metal material such as aluminum. The reflecting member 53 has a reflecting surface 53r which is opposed to the second face 50b of the wavelength conversion member 50, and which reflects the fluorescence Y. The reflecting surface 53r can be a surface of the metal material itself, or can be formed of a metal film or a dielectric multilayer film formed on the surface of the metal material.

In the light source device 100, when the excitation light E emitted from the light emitting element 56 enters the wavelength conversion member 50, the phosphor included in the wavelength conversion member 50 is excited, and the fluorescence Y is emitted from an arbitrary light emitting point. The fluorescence Y proceeds from the arbitrary light emitting point toward all directions, but the fluorescence Y proceeding toward the side surfaces 50g proceeds toward the first face 50a or the second face 50b while repeating the total reflection at a plurality of places in the side surfaces 50g. The fluorescence Y proceeding toward the first face 50a enters the angle conversion member 52. Meanwhile, the fluorescence Y proceeding toward the second face 50b is reflected by the reflecting member 53, and then proceeds toward the first face 50a.

A part of the excitation light E which has not been used for the excitation of the phosphor out of the excitation light E having entered the wavelength conversion member 50 is reflected by a member on the periphery of the wavelength conversion member 50 including the light emitting element 56 of the light source 51, or the reflecting member 53 disposed on the second face 50b. Therefore, the part of the excitation light E is confined inside the wavelength conversion member 50 to be reused.

The angle conversion member 52 is disposed on the light exit side of the first face 50a of the wavelength conversion member 50. The angle conversion member 52 is formed of, for example, a taper rod. The angle conversion member 52 has a plane of incidence of light 52a which the fluorescence Y emitted from the wavelength conversion member 50 enters, a light exit surface 52b for emitting the fluorescence Y, and a side surface 52c for reflecting the fluorescence Y toward the light exit surface 52b.

The angle conversion member 52 has a truncated quadrangular pyramid-like shape, and the area of a cross-section perpendicular to an optical axis J increases along the proceeding direction of the light. Therefore, the area of the light exit surface 52b is larger than the area of the plane of incidence of light 52a. An axis which passes through the center of the light exit surface 52b and the center of the plane of incidence of light 52a, and is parallel to the X axis is defined as the optical axis J of the angle conversion member 52. It should be noted that the optical axis J of the angle conversion member 52 coincides with the optical axis AX1 of the first illumination device 20.

The fluorescence Y having entered the angle conversion member 52 changes the direction so as to approximate to a direction parallel to the optical axis J every time the fluorescence Y is totally reflected by the side surface 52c while proceeding inside the angle conversion member 52. In such a manner, the angle conversion member 52 converts an exit angle distribution of the fluorescence Y emitted from the first face 50a of the wavelength conversion member 50. Specifically, the angle conversion member 52 makes a maximum exit angle of the fluorescence Y in the light exit surface 52b smaller than a maximum incident angle of the fluorescence Y in the plane of incidence of light 52a.

In general, since an etendue of light defined by a product of the area of the light exit region and a solid angle (the maximum exit angle) of the light is conserved, the etendue of the fluorescence Y is also conserved before and after the transmission through the angle conversion member 52. As described above, the angle conversion member 52 in the present embodiment has the configuration in which the area of the light exit surface 52b is made larger than the area of the plane of incidence of light 52a. Therefore, from a viewpoint of the conservation of the etendue, it is possible for the angle conversion member 52 in the present embodiment to make the maximum exit angle of the fluorescence Y in the light exit surface 52b smaller than the maximum incident angle of the fluorescence Y entering the plane of incidence of light 52a.

The angle conversion member 52 is fixed to the wavelength conversion member 50 via the bonding member 59 so that the plane of incidence of light 52a is opposed to the first face 50a of the wavelength conversion member 50. In other words, the bonding member 59 is disposed between the angle conversion member 52 and the first face 50a of the wavelength conversion member 50.

It is also possible to use a compound parabolic concentrator (CPC) instead of the taper rod as the angle conversion member 52. Even when using the CPC as the angle conversion member 52, it is also possible to obtain substantially the same advantages as those when using the taper rod. It should be noted that the light source device 100 is not necessarily required to be provided with the angle conversion member 52.

The integrator optical system 70 has a first lens array 61 and a second lens array 101. The integrator optical system 70 constitutes a homogenous illumination optical system for homogenizing an intensity distribution of the fluorescence Y emitted from the light source device 100 in each of the light modulation devices 4R, 4G as the illumination target area in cooperation with the superimposing optical system 103. The fluorescence Y emitted from the light exit surface 52b of the angle conversion member 52 enters the first lens array 61. The first lens array 61 constitutes the integrator optical system 70 together with the second lens array 101 disposed in a posterior stage of the light source device 100.

The first lens array 61 has a plurality of first small lenses 61a. The plurality of first small lenses 61a is arranged in a matrix in a plane parallel to a Y-Z plane perpendicular to the optical axis AX1 of the first illumination device 20. The plurality of first small lenses 61a divides the fluorescence Y emitted from the angle conversion member 52 into a plurality of partial light beams. A shape of each of the first small lenses 61a is a rectangular shape substantially similar to a shape of each of the image formation areas of the light modulation devices 4R, 4G. Thus, each of partial light beams emitted from the first lens array 61 efficiently enters each of the image formation areas of the light modulation devices 4R, 4G.

The fluorescence Y emitted from the first lens array 61 proceeds toward the second lens array 101. The second lens array 101 is arranged so as to be opposed to the first lens array 61. The second lens array 101 has a plurality of second small lenses 101a corresponding to the plurality of first small lenses 61a of the first lens array 61. The second lens array 101 focuses an image of each of the first small lenses 61a of the first lens array 61 in the vicinity of each of the image formation areas of the light modulation devices 4R, 4G in cooperation with the superimposing optical system 103. The plurality of second small lenses 101a is arranged in a matrix in a plane parallel to the Y-Z plane perpendicular to the optical axis AX1 of the first illumination device 20.

Each of the first small lenses 61a of the first lens array 61 and each of the second small lenses 101a of the second lens array 101 have respective sizes the same as each other in the present embodiment, but can have respective sizes different from each other. Further, the first small lenses 61a of the first lens array 61 and the second small lenses 101a of the second lens array 101 are arranged at positions where respective optical axes coincide with each other in the present embodiment, but can be arranged in a state in which the axes are shifted from each other.

The polarization conversion element 102 converts the polarization direction of the fluorescence Y emitted from the second lens array 101. Specifically, the polarization conversion element 102 converts each of the partial light beams of the fluorescence Y which is divided by the first lens array 61, and is emitted from the second lens array 101 into linearly polarized light.

The polarization conversion element 102 has a polarization splitting layer (not shown) for transmitting one of the linearly polarized components included in the fluorescence Y emitted from the light source device 100 without modification while reflecting the other of the linearly polarized components toward a direction perpendicular to the optical axis AX1, a reflecting layer (not shown) for reflecting the other of the linearly polarized components reflected by the polarization splitting layer, toward a direction parallel to the optical axis AX1, and a wave plate (not shown) for converting the other of the linearly polarized components reflected by the reflecting layer into the one of the linearly polarized components.

In the case of the present embodiment, the second face 50b of the wavelength conversion member 50 is a rough surface. In contrast, the reflecting surface 53r of the reflecting member 53 is a smooth surface. It is desirable for the surface roughness of the second face 50b to be no smaller than 2 μm in arithmetic mean roughness. Further, it is more desirable for the surface roughness of the second face 50b to be no smaller than 10 μm in arithmetic mean roughness. Further, a pitch between a ridge and a bottom adjacent to each other of the rough surface is desirably no smaller than the wavelength band of the fluorescence Y, and is desirably no smaller than, for example, 0.7 μm. A part of the second face 50b of the wavelength conversion member 50 has contact with the reflecting surface 53r of the reflecting member 53. It is desirable for the surface roughness of the reflecting surface 53r to be smaller than 2 μm in arithmetic mean roughness. As a method of making the second face 50b of the wavelength conversion member 50 as the rough surface, there are cited a method of cutting the second face 50b of the wavelength conversion member 50 with a wire saw, a method of sandblasting the second face 50b, a method of performing abrasive processing on the second face 50b with an abrasive compound such as alumina, and so on.

### Comparative Example

Then, a light source device according to a comparative example will be described.

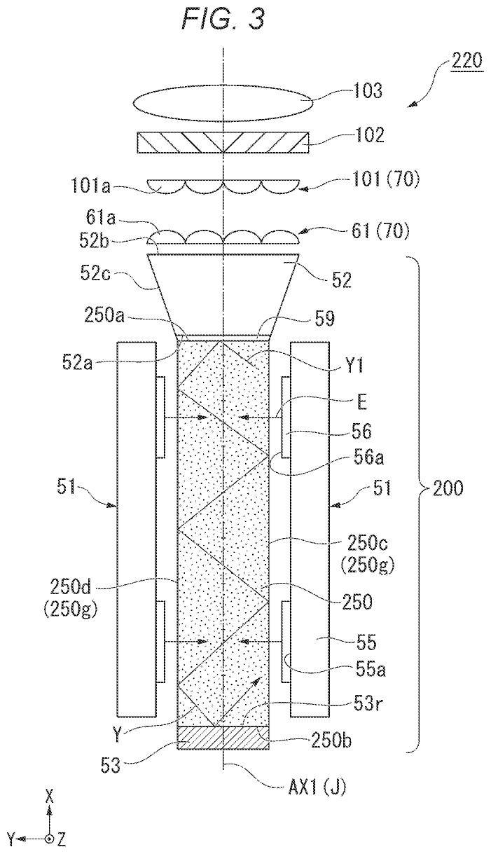

FIG. 3 is a schematic configuration diagram of a first illumination device 220 according to the comparative example.

As shown in FIG. 3, the first illumination device 220 according to the comparative example is provided with a light source device 200. The light source device 200 is provided with the light emitting elements 56, a wavelength conversion member 250, the reflecting member 53, and the angle conversion member 52. The light source device 200 according to the comparative example is different from the light source device 100 according to the present embodiment only in a configuration of the wavelength conversion member 250. Therefore, in FIG. 3, members other than the wavelength conversion member 250 are denoted by the reference symbols common to FIG. 2, and the description thereof will be omitted.

As shown in FIG. 3, in the light source device 200 according to the comparative example, a second face 250b of the wavelength conversion member 250 is not such a rough surface as in the present embodiment, but is a smooth surface. Further, the reflecting surface 53r of the reflecting member 53 is a smooth surface. The second face 250b and the reflecting surface 53r have contact with each other.

In the light source device of this kind, in general, the angle conversion member is formed of a transparent material such as glass, the bonding member is formed of an optical adhesive, and the wavelength conversion member includes a phosphor material. In this case, a refractive index of the angle conversion member and a refractive index of the bonding member substantially coincide with each other, and the refractive index of the angle conversion member and a refractive index of the wavelength conversion member are different from each other. In general, the optical adhesive is lower in refractive index than the wavelength conversion member.

Therefore, as shown in FIG. 3, the fluorescence Y which enters a first face 250a of the wavelength conversion member 250 at an incident angle equal to or larger than the critical angle out of the fluorescence having reached the first face 250a is totally reflected by an interface between the first face 250a of the wavelength conversion member 250 and the bonding member 59, proceeds toward the second face 250b, and then enters the second face 250b. In the case of the light source device 200 according to the comparative example, since both of the second face 250b of the wavelength conversion member 250 and the reflecting surface 53r of the reflecting member 53 are the smooth surfaces, fluorescence Y1 having entered the second face is totally reflected without changing the angle, and then proceeds toward the first face 250a once again.

As a result, the fluorescence Y1 repeatedly propagates inside the wavelength conversion member 250 in the state in which the angle is conserved, and is therefore confined inside the wavelength conversion member 250. In the light source device 200 according to the comparative example, since the fluorescence Y1 of this kind exists, an extraction efficiency of the whole of the fluorescence decreases, and there is a possibility that it is unachievable to obtain the fluorescence having the desired intensity.

### Advantages of First Embodiment

The light source device 100 according to the present embodiment is provided with the light emitting element 56 having the light emitting surface 56a for emitting the excitation light E having the first wavelength band, the wavelength conversion member 50 which includes the phosphor to convert the excitation light E emitted from the light emitting element 56 into the fluorescence Y having the second wavelength band different from the first wavelength band, and the reflecting member 53 having the reflecting surface 53r for reflecting the fluorescence Y generated in the wavelength conversion member 50. The wavelength conversion member 50 has the first face 50a which crosses the longitudinal direction of the wavelength conversion member 50, and which emits the fluorescence Y, the second face 50b which crosses the longitudinal direction of the wavelength conversion member 50, and which is located at the opposite side to the first face 50a, and the side surfaces 50g crossing the first face 50a and the second face 50b. The light emitting surface 56a is disposed so as to be opposed to at least a part of the side surfaces 50g. The reflecting surface 53r is disposed so as to be opposed to the second face 50b. The second face 50b is a rough surface, and the reflecting surface 53r is a smooth surface.

According to the light source device 100 related to the present embodiment, as shown in FIG. 2, the fluorescence Y1 which is totally reflected by the first face 50a of the wavelength conversion member 50, and then enters the second face 50b is reflected in a scattered manner by the second face 50b formed of the rough surface, and therefore, there is generated fluorescence Y2 having the angle variously changed.

Thus, at least a part of the fluorescence Y2 reflected in a scattered manner by the second face 50b enters the first face 50a of the wavelength conversion member 50 at the incident angle smaller than the critical angle, and is therefore transmitted through the first face 50a and taken out to the outside of the light source device 100 without being totally reflected by the first face 50a.

As described hereinabove, according to the light source device 100 related to the present embodiment, it is possible to provide the light source device which is high in extraction efficiency of the fluorescence Y compared to the light source device 200 according to the comparative example, and is easy to obtain the fluorescence Y having the desired intensity.

The light source device 100 according to the present embodiment is further provided with the angle conversion member 52 which is disposed so as to be opposed to the first face 50a, and converts the angle distribution of the fluorescence Y emitted from the first face 50a, and the bonding member 59 disposed between the angle conversion member 52 and the first face 50a.

According to this configuration, even in a configuration in which the refractive index of the angle conversion member 52 and the refractive index of the wavelength conversion member 50 are different from each other, and it is easy for the fluorescence Y to totally be reflected by the first face 50a of the wavelength conversion member 50, by the fluorescence Y1 being reflected in a scattered manner by the second face 50b, it becomes easy for the fluorescence Y1 to be taken out to the outside of the light source device 100. Further, by the fluorescence Y emitted from the first face 50a of the wavelength conversion member 50 being transmitted through the angle conversion member 52, the angle distribution of the fluorescence Y is narrowed. Thus, it is possible to increase the light use efficiency in the optical system in the posterior stage of the light source device 100.

The projector 1 according to the present embodiment is equipped with the light source device 100 according to the present embodiment, and is therefore excellent in light use efficiency.

### Second Embodiment

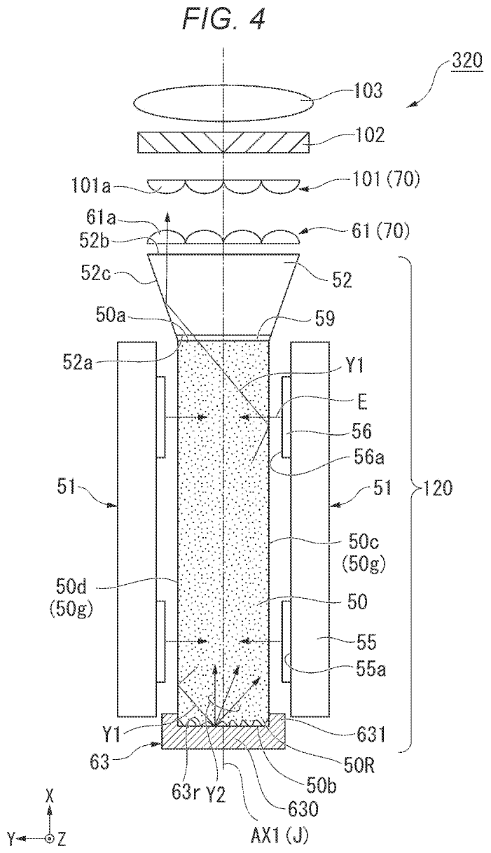

Then, a second embodiment of the present disclosure will be described using FIG. 4.

A basic configuration of a projector and a light source device according to the second embodiment is substantially the same as that in the first embodiment, and therefore, the description of the basic configuration of the projector and the light source device will be omitted.

FIG. 4 is a schematic configuration diagram of a first illumination device 320 according to the second embodiment.

In FIG. 4, the constituents common to the drawing used in the first embodiment are denoted by the same reference symbols, and the description thereof will be omitted.

As shown in FIG. 4, the first illumination device 320 according to the present embodiment is provided with a light source device 120. The light source device 120 is provided with the light emitting elements 56, the wavelength conversion member 50, a reflecting member 63, the angle conversion member 52, and the bonding member 59.

In the light source device 120 according to the present embodiment, the reflecting member 63 has a base 630 and a wall 631. The base 630 is disposed so as to be opposed to the second face 50b, and has a reflecting surface 63r opposed to the second face 50b. The wall 631 continues from the base 630, and is disposed so as to be opposed to a part of the side surfaces 50g at a side near to the second face 50b. In other words, in contrast to the reflecting member 53 in the first embodiment which is opposed only to the second face 50b, the reflecting member 63 in the present embodiment is also opposed to a part of the side surfaces 50g in addition to the second face 50b. The base 630 and the wall 631 are formed of an integrated single member in the case of the present embodiment, but can also be formed of separated members. The rest of the configuration of the light source device 120 is substantially the same as in the first embodiment.

### Advantages of Second Embodiment

Also in the present embodiment, it is possible to obtain substantially the same advantages as in the first embodiment such as an advantage that it is possible to realize the light source device 120 which is high in extraction efficiency of the fluorescence Y, and is easy to obtain the fluorescence Y having the desired intensity.

Further, in the light source device 120 according to the present embodiment, the reflecting member 63 has the base 630 disposed so as to be opposed to the second face 50b, and the wall 631 which continues from the base 630, and is disposed so as to opposed to a part of the side surfaces 50g.

In the case of the first embodiment, there is a possibility that the fluorescence Y which enters a corner between the second face 50b of the wavelength conversion member 50 and the side surface 50g is leaked outside. In contrast, according to the configuration of the present embodiment, since the corner 50R between the second face 50b of the wavelength conversion member 50 and the side surface 50g is covered with the reflecting member 63, the fluorescence Y which enters the corner 50R between the second face 50b of the wavelength conversion member 50 and the side surface 50g can be reflected to thereby be returned to the wavelength conversion member 50, and thus, it is possible to reduce a loss of the fluorescence Y.

### Third Embodiment

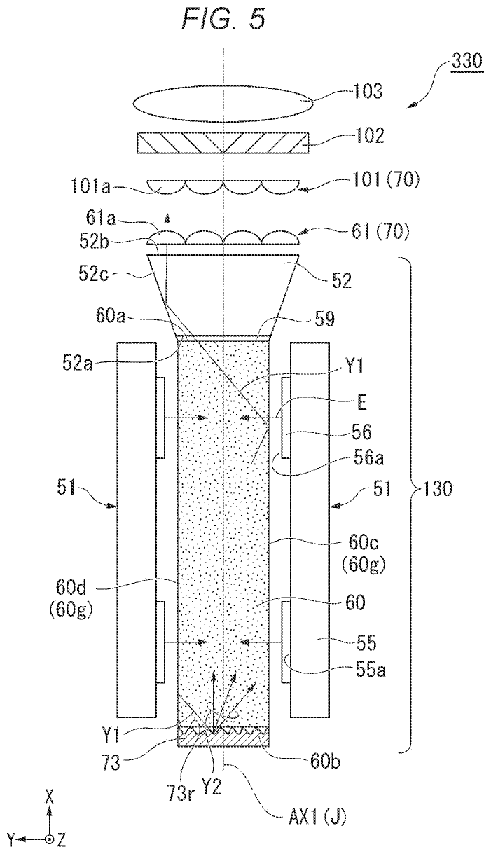

Then, a third embodiment of the present disclosure will be described using FIG. 5.

A basic configuration of a projector and a light source device according to the third embodiment is substantially the same as that in the first embodiment, and therefore, the description of the basic configuration of the projector and the light source device will be omitted.

FIG. 5 is a schematic configuration diagram of a first illumination device 330 according to the third embodiment.

In FIG. 5, the constituents common to the drawings used in the previous embodiments are denoted by the same reference symbols, and the description thereof will be omitted.

As shown in FIG. 5, the first illumination device 330 according to the present embodiment is provided with a light source device 130. The light source device 130 is provided with the light emitting elements 56, a wavelength conversion member 60, a reflecting member 73, the angle conversion member 52, and the bonding member 59. The wavelength conversion member 60 has a first face 60a, a second face 60b, and a side surface 60g including a third face 60c and a fourth face 60d. The reflecting member 73 has a reflecting surface 73r opposed to the second face 60b.

In the case of the present embodiment, the second face 60b of the wavelength conversion member 60 is a smooth surface. In contrast, the reflecting surface 73r of the reflecting member 73 is a rough surface. Specifically, the reflecting surface 73r of the reflecting member 73 has a concavo-convex structure. A shape of a protrusion constituting the concavo-convex structure can be, for example, a semispherical shape, a pyramidal shape, or a columnar shape, or can also be an amorphous shape. The height of the protrusion is desirably, for example, about 1 μm through 0.2 mm. A distance between the protrusion and the recess adjacent to each other is desirably, for example, about 1 μm through 0.2 mm. The protrusions and the recesses can be arranged at regular intervals, or are not required to be arranged periodically. Further, it is desirable for the surface roughness of the second face 60b of the wavelength conversion member 60 to be smaller than 2 μm in arithmetic mean roughness. The rest of the configuration of the light source device 130 is substantially the same as in the first embodiment. As a method of making the reflecting member 73 as the rough surface, there are cited a method of sandblasting the reflecting surface 73r, and a method of performing abrasive processing on the reflecting surface 73r with an abrasive compound such as alumina. Further, as a method of forming the concavo-convex structure on the reflecting surface 73r of the reflecting member 73, there are cited a method of providing a mask to the reflecting member 73 made of metal such as alumina and then performing wet etching, and a method of etching a base member of the reflecting member 73 to form a concavo-convex pattern, and then forming a reflecting surface on the concavo-convex pattern by evaporation of a metal film or evaporation of a dielectric multilayer film.

### Advantages of Third Embodiment

In the case of the present embodiment, a part of the fluorescence Y1 which has entered the second face 60b at an angle smaller than the critical angle is transmitted through the second face 60b, and then enters the reflecting surface 73r of the reflecting member 73. Since the reflecting surface 73r formed of the rough surface reflects and scatters the fluorescence Y1 which has been transmitted through the second face 60b, there is generated the fluorescence Y2 having the angle variously changed.

Thus, at least a part of the fluorescence Y2 reflected in a scattered manner by the reflecting surface 73r enters the first face 60a of the wavelength conversion member 60 at the incident angle smaller than the critical angle, and is therefore transmitted through the first face 60a and taken out to the outside of the light source device 130 without being totally reflected by the first face 60a.

Therefore, also in the present embodiment, it is possible to obtain substantially the same advantages as in the first embodiment such as an advantage that it is possible to realize the light source device 130 which is high in extraction efficiency of the fluorescence Y, and is easy to obtain the fluorescence Y having the desired intensity.

Further, in the present embodiment, since the reflecting surface 73r of the reflecting member 73 has the concavo-convex structure, and the second face 60b of the wavelength conversion member 60 is the smooth surface, when the processing of the end surface of the wavelength conversion member 60 is difficult, it is possible to easily manufacture the light source device 130.

### Fourth Embodiment

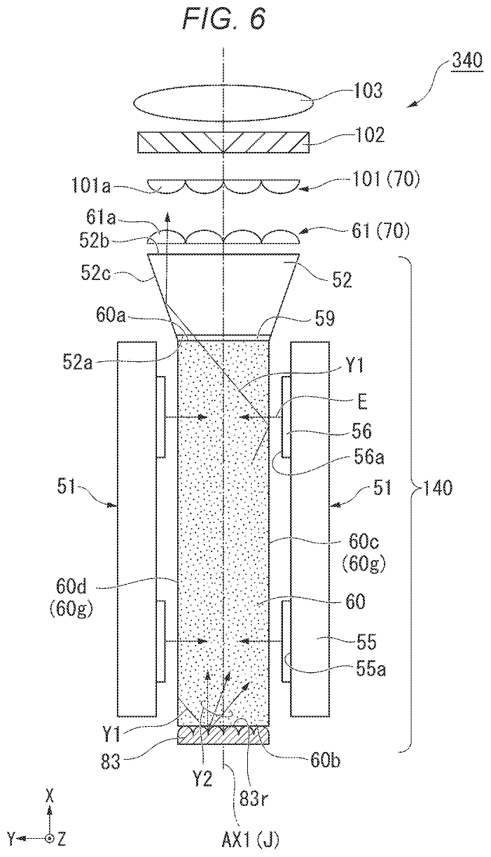

Then, a fourth embodiment of the present disclosure will be described using FIG. 6.

A basic configuration of a projector and a light source device according to the fourth embodiment is substantially the same as that in the first embodiment, and therefore, the description of the basic configuration of the projector and the light source device will be omitted.

FIG. 6 is a schematic configuration diagram of a first illumination device 340 according to the fourth embodiment.

In FIG. 6, the constituents common to the drawings used in the previous embodiments are denoted by the same reference symbols, and the description thereof will be omitted.

As shown in FIG. 6, the first illumination device 340 according to the present embodiment is provided with a light source device 140. The light source device 140 is provided with the light emitting elements 56, the wavelength conversion member 60, a reflecting member 83, the angle conversion member 52, and the bonding member 59. The reflecting member 83 has a reflecting surface 83r opposed to the second face 60b.

In the case of the present embodiment, the second face 60b of the wavelength conversion member 60 is a smooth surface. The reflecting surface 83r of the reflecting member 83 is a rough surface. Specifically, the reflecting surface 83r of the reflecting member 83 has a structure in which a plurality of fine protrusions each shaped like a curved surface is arranged periodically. The diameter of the protrusion shaped like a curved surface is desirably, for example, about 1 μm through 0.2 mm. The plurality of protrusions each shaped like a curved surface can be arranged at regular intervals, or is not required to be arranged periodically. The rest of the configuration of the light source device 140 is substantially the same as in the first embodiment. The reflecting surface 83r can be realized by forming the reflecting member 83 from a metal material such as alumina, or it is possible to form a metal film or a dielectric multilayer film on the reflecting surface 83r using evaporation or the like.

### Advantages of Fourth Embodiment

Also in the present embodiment, since the reflecting surface 83r formed of the rough surface reflects and scatters the fluorescence Y1 which has been transmitted through the second face 60b, there is generated the fluorescence Y2 having the angle variously changed. Therefore, it is possible to obtain substantially the same advantages as in the first embodiment such as an advantage that it is possible to realize the light source device 140 which is high in extraction efficiency of the fluorescence Y, and is easy to obtain the fluorescence Y having the desired intensity.

In the present embodiment, since the reflecting surface 83r of the reflecting member 83 has the structure in which the protrusions each shaped like a curved surface are arranged periodically, when the processing of the end surface of the wavelength conversion member 60 is difficult, it is possible to easily manufacture the light source device 140 similarly to the third embodiment. Further, by appropriately designing the shape and the dimension of the protrusion shaped like a curved surface, it is possible to adjust the reflection angle of the fluorescence Y1 by the reflecting surface 83r to control the angle distribution of the fluorescence Y2 thus reflected.

### Fifth Embodiment

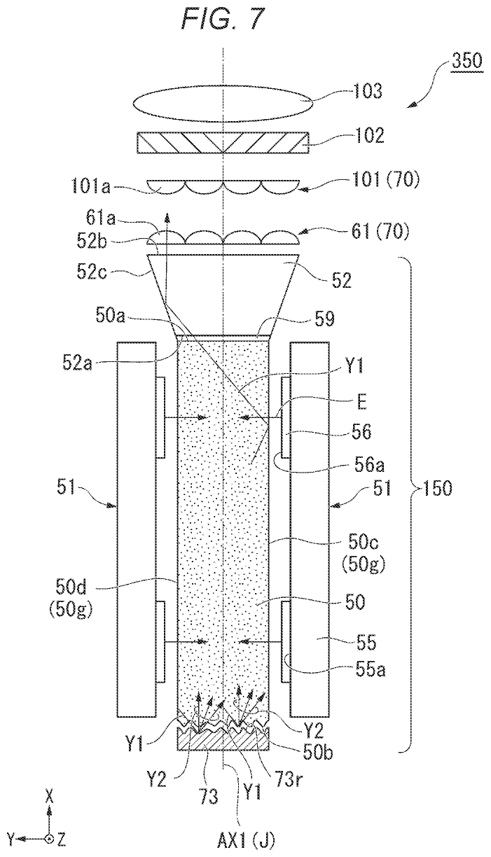

Then, a fifth embodiment of the present disclosure will be described using FIG. 7.

A basic configuration of a projector and a light source device according to the fifth embodiment is substantially the same as that in the first embodiment, and therefore, the description of the basic configuration of the projector and the light source device will be omitted.

FIG. 7 is a schematic configuration diagram of a first illumination device 350 according to the fifth embodiment.

In FIG. 7, the constituents common to the drawings used in the previous embodiments are denoted by the same reference symbols, and the description thereof will be omitted.

As shown in FIG. 7, the first illumination device 350 according to the present embodiment is provided with a light source device 150. The light source device 150 is provided with the light emitting elements 56, the wavelength conversion member 50, the reflecting member 73, the angle conversion member 52, and the bonding member 59.

In the case of the present embodiment, the second face 50b of the wavelength conversion member 50 is a rough surface. The reflecting surface 73r of the reflecting member 73 is a rough surface. In the present embodiment, both of the second face 50b and the reflecting surface 73r are rough surfaces. It is desirable for the surface roughness of both of the second face 50b and the reflecting surface 73r to be no smaller than 2 μm in arithmetic mean roughness. Further, it is more desirable for the surface roughness of both of the second face 50b and the reflecting surface 73r to be no smaller than 10 μm in arithmetic mean roughness. Further, a pitch between a ridge and a bottom adjacent to each other of the rough surface of the second face 50b and the reflecting surface 73r is desirably no smaller than the wavelength band of the fluorescence Y, and is desirably no smaller than, for example, 0.7 μm. The reflecting surface 73r can be provided with the concavo-convex structure, or can also be provided with the structure in which the protrusions each shaped like a curved surface are arranged periodically. The rest of the configuration of the light source device 150 is substantially the same as in the first embodiment.

### Advantages of Fifth Embodiment

Also in the present embodiment, it is possible to obtain substantially the same advantages as in the first embodiment such as an advantage that it is possible to realize the light source device 150 which is high in extraction efficiency of the fluorescence Y, and is easy to obtain the fluorescence Y having the desired intensity. Further, similarly to the third embodiment, since the fluorescence Y1 having been transmitted through the second face 50b is reflected in a scattered manner by the reflecting surface 73r formed of the rough surface to turn to the fluorescence Y2 having the angle variously changed, it is possible to further increase the extraction efficiency of the fluorescence Y.

It should be noted that the scope of the present disclosure is not limited to the embodiments described above, and a variety of modifications can be provided thereto within the scope or the spirit of the present disclosure. Further, one aspect of the present disclosure can be provided with a configuration obtained by arbitrarily combining characterizing portions of the respective embodiments described above with each other.

Further, the specific descriptions of the shape, the number, the arrangement, the material, and so on of the constituents of the light source device and the projector are not limited to those in the embodiments described above, and can arbitrarily be modified. Further, although in the embodiments described above, there is described the example of installing the light source device according to the present disclosure in the projector using the liquid crystal panels, the example is not a limitation. The light source device according to the present disclosure can also be applied to a projector using digital micromirror devices as the light modulation devices. Further, the projector is not required to have a plurality of light modulation devices, and can be provided with just one light modulation device.

Although in the embodiments described above, there is described the example of applying the light source device according to the present disclosure to the projector, the example is not a limitation. The light source device according to the present disclosure can also be applied to lighting equipment, a headlight of a vehicle, and so on.

A light source device according to an aspect of the present disclosure may have the following configuration.

The light source device according to an aspect of the present disclosure includes a light emitting element having a light emitting surface configured to emit first light having a first wavelength band, a wavelength conversion member which includes a phosphor, and which is configured to convert the first light emitted from the light emitting element into second light having a second wavelength band different from the first wavelength band, and a reflecting member having a reflecting surface configured to reflect the second light generated by the wavelength conversion member, wherein the wavelength conversion member has a first face which crosses a longitudinal direction of the wavelength conversion member, and which emits the second light, a second face which crosses the longitudinal direction of the wavelength conversion member, and which is located at an opposite side to the first face, and a third face crossing the first face and the second face, the light emitting surface is disposed so as to be opposed to at least a part of the third face, the reflecting surface is disposed so as to be opposed to the second face, and at least one of the second face and the reflecting surface is a rough surface.

The light source device according to an aspect of the present disclosure can be provided with a configuration in which the second face is a rough surface, and the reflecting surface is a smooth surface.

The light source device according to an aspect of the present disclosure can be provided with a configuration in which the second face is a smooth surface, and the reflecting surface is a rough surface.

The light source device according to an aspect of the present disclosure can be provided with a configuration in which the reflecting surface has a concavo-convex structure.

The light source device according to an aspect of the present disclosure can be provided with a configuration in which the reflecting surface has a structure in which protrusions shaped like a curved surface are arranged periodically.

The light source device according to an aspect of the present disclosure can be provided with a configuration in which the reflecting member has a base disposed so as to be opposed to the second face, and a wall which continues from the base and is disposed so as to be opposed to a part of the third face.

The light source device according to an aspect of the present disclosure can be provided with a configuration in which there are further included an angle conversion member which is disposed so as to be opposed to the first face, and which is configured to convert an angle distribution of the second light emitted from the first face, and a bonding member disposed between the angle conversion member and the first face.

A projector according to an aspect of the present disclosure may have the following configuration.

The projector according to an aspect of the present disclosure includes the light source device according to the aspect of the present disclosure, a light modulation device configured to modulate light including the second light emitted from the light source device in accordance with image information, and a projection optical device configured to project the light modulated by the light modulation device.

What is claimed is:

1. A light source device comprising:
a light emitting element having a light emitting surface configured to emit first light having a first wavelength band;
a wavelength conversion member which includes a phosphor, and which is configured to convert the first light emitted from the light emitting element into second light having a second wavelength band different from the first wavelength band; and
a reflecting member having a reflecting surface configured to reflect the second light generated by the wavelength conversion member, wherein
the wavelength conversion member has a first face which crosses a longitudinal direction of the wavelength conversion member, and which emits the second light, a second face which crosses the longitudinal direction of the wavelength conversion member, and which is located at an opposite side to the first face, and a third face crossing the first face and the second face,
the light emitting surface is disposed so as to be opposed to at least a part of the third face,
the reflecting surface is disposed so as to be opposed to the second face, and
at least one of the second face and the reflecting surface is a rough surface.

2. The light source device according to claim 1, wherein
the second face is a rough surface, and the reflecting surface is a smooth surface.

3. The light source device according to claim 1, wherein
the second face is a smooth surface, and the reflecting surface is a rough surface.

4. The light source device according to claim 1, wherein
the rough surface has a concavo-convex structure.

5. The light source device according to claim 1, wherein
the rough surface has a structure in which protrusions shaped like a curved surface are arranged periodically.

6. The light source device according to claim 1, wherein
the reflecting member has a base disposed so as to be opposed to the second face, and a wall which continues from the base and is disposed so as to be opposed to a part of the third face.

7. The light source device according to claim 1, further comprising:
an angle conversion member which is disposed so as to be opposed to the first face, and which is configured to convert an angle distribution of the second light emitted from the first face; and
a bonding member disposed between the angle conversion member and the first face.

8. A projector comprising:
the light source device according to claim 1;
a light modulation device configured to modulate light including the second light emitted from the light source device in accordance with image information; and
a projection optical device configured to project the light modulated by the light modulation device.
